(19) United States
(12) Patent Application Publication
(10) Pub. No.: US 2004/0124003 A1
(43) Pub. Date: Jul. 1, 2004

(54) Double-sided printed circuit board without via holes and method of fabricating the same

(76) Inventors: Chang-Sup Ryu, Daejeon-si (KR); Jang-Kyu Kang, Dacjeon-si (KR); Byung-Kook Sun, Daejeon-si (KR)

Correspondence Address: GOTTLIEB RACKMAN & REISMAN PC, 270 MADISON AVENUE, 8TH FLOOR, NEW YORK, NY, 100160601

(21) Appl. No.: 10/414,946

(22) Filed: Apr. 16, 2003

(30) Foreign Application Priority Data
Dec. 30, 2002 (KR) 2002-87613

(51) Int. Cl. H05K 3/02; H05K 1/00

(52) U.S. Cl. 174/254; 29/829; 29/846; 29/831

(57) ABSTRACT

Disclosed is a method of fabricating a double-sided PCB without via holes, functioning to transport electric signals between both sides of the PCB, by folding a flexible substrate, in which circuit patterns are formed on only one side of the flexible substrate, and the double-sided PCB without the via holes fabricated by the method. Therefore, the method is advantageous in that it allows PCB manufacturers to save the efforts for forming and protecting the via holes because the double-sided PCB does not need via holes, and reduces its fabricating cost and time, due to simplicity of this method.

### BACKGROUND OF THE INVENTION

1. Field of the invention

The present invention relates, in general, to a method of fabricating a double-sided printed circuit board (PCB) and, in particular, to a method of fabricating a double-sided PCB without via holes by folding a flexible substrate, onto which a circuit pattern is formed on only one side thereof, and to a double-sided PCB without the via holes fabricated by the method.

2. Description of the Prior Art

As well known to those skilled in the art, PCBs are classified into three types according to the number of layers constituting the PCBs: a single-sided PCB in which patterns are formed on only one side of an insulating substrate, a double-sided PCB in which patterns are formed on both sides of the insulating substrate, and a multi-layered board (MLB) in which patterns are formed on multiple layers. Conventionally, the single-sided PCB was most popular because electronic parts generally have simple structures and their circuit patterns are not complicated. However, recently, the double-sided PCB or MLB is frequently being used in accordance with the increasing need for highly integrated, complicated, and fine circuit patterns.

Most useful as a material of the double-sided PCB is a copper clad laminate (CCL) in which thin copper layers are plated on both sides of the insulating substrate.

In the case of double-sided PCBs or MLBs, electric signals are transported between an upper and a lower side or an inner and an outer layer of the double-sided PCB or MLB through via holes located throughout the upper and lower sides or the inner and outer layers.

The via holes are formed through a substrate, for example, by using a drill, and an inner wall of each via hole is copper-plated to form a conductive plated layer on itself. Additionally, an insulating ink is filled into the space remaining inside the via hole.

As described above, the via hole functions to electrically connect the PCB's upper side to its lower side.

Alternatively, the PCB is classified into three cases in accordance with a material of the PCB; a rigid PCB, a flexible PCB, and a rigid-flexible PCB.

The rigid PCB is a widely known PCB and is of a shape not easily deformed, but the flexible PCB is used in case that the PCB needs to be bent or folded in electronic equipment having non-hexahedral design. Furthermore, the flexible PCB is used as a connector for electrically connecting a driving part, such as a printer head, to another component.

A rigid-flexible PCB is a combined form of the rigid PCBs with the flexible PCB, and is mostly used in aerospace and military equipment because of its sophisticated circuit pattern and improved reliability due to reduced electrical connection portions. Recently, the rigid-flexible PCB is also being used to electrically connect folded parts of a folder-type portable phones to each other. Even though the rigid-flexible PCB is disadvantageous in that its productivity is low because it is fabricated by combining substrates made of different materials and it is difficult to secure such sophisticated technology, there remains a need to improve the method of fabricating the rigid-flexible PCB because use of the rigid-flexible PCB is rapidly increasing according to the trend of complicated and small-sized electronic goods.

FIGS. 1A to 1G are sectional views step wisely illustrating a fabricating process of a conventional double-sided PCB.

In detail, FIG. 1A shows a rigid copper clad laminate (CCL) used to fabricate the conventional double-sided PCB. At this time, reference numerals 11 and 12 denote a copper layer and an insulating layer, respectively.

In FIG. 1B, via holes 13 are formed through the copper clad laminate using a drill to electrically connect an upper side of the CCL to a lower side of the CCL. The via holes may be formed by a mechanical drill, a YAG laser, or a CO₂ laser. The resulting CCL is electroless-copper plated in FIG. 1C, and then electrolytic-copper plated as shown in FIG. 1D. Referring to FIG. 1E, a circuit pattern 16 is formed on the copper-plated CCL.

To facilitate understanding, the most frequently-used conventional method of forming a circuit pattern will be described below. The conventional method depends on physical properties of the substrate and fabricating conditions of the PCB.

Various methods of forming the circuit pattern on the substrate all are based on an etching (eroding) and plating (layering) process. In other words, the desirably patterned substrate is fabricated properly using these two processes.

FIGS. 2A to 2D schematically illustrate the fabricating process of the PCB, and is called a “subtractive process”. FIGS. 2A to 2D may be substituted by FIGS. 1C to 1E in the “subtractive process”. The term “subtractive process” generally means a process of forming a circuit pattern using an etching method, but in the present specification, “subtractive process” means a process conducted according to a following description.

FIG. 2A shows a CCL through which a hole is formed, and which is electroless-copper plated in a thickness of 0.5 to 1.5 μm. At this time, reference numerals 21, 22, and 24 denote a copper layer of the CCL, an insulating layer of the CCL, and an electrolytic-copper plated layer, respectively.

Further, FIG. 2B illustrates the electroless-copper plated CCL on which an electrolytic-copper plated layer 25 with a thickness of 15 to 25 μm is formed.

The reason that the electroless-copper plating process is conducted before the electrolytic-copper plating process is that the electrolytic-copper plating process using electricity can not be accomplished on the insulating layer. In other words, the electroless-copper plating process is conducted to form a thin conductive film on the CCL so as to conduct the electrolytic-copper plating process. Furthermore, it is preferable that a conductive part of the circuit pattern is formed by the electrolytic-copper plating process, because it is difficult to conduct the electroless-copper plating process, and economic efficiency of the electroless-copper plating process is poor.

In FIG. 2C, an etching resist pattern 26 is formed on the electrolytic-copper plated CCL using an artwork film on which a dry film (D/F) and a circuit pattern are printed.

Various processes exist for constructing a resist pattern on the PCB according to the previously designed circuit pattern, but a process using dry film is most popular.

The dry film is generally expressed by D/F, and comprises three layers: a cover film layer, a photo-resist film layer, and a Mylar film layer. Of the three layers, the photo-resist film layer substantially acts as a resist.

When the dry film is coated on the electrolytic-copper plated CCL while the cover film is peeled from the dry film (lamination process), the artwork film onto which a circuit wire is printed is attached to the resulting CCL, and an ultraviolet ray is irradiated to the resulting structure, the ultraviolet ray is not penetrated through a black portion on which the artwork pattern is printed, but penetrated through a portion other than the black portion, to cure the dry film. If the resultant structure which is irradiated by the UV is dipped into a developing liquid, a non-cured dry film portion is removed by the developing liquid, and the cured dry film portion forms the resist pattern on the PCB. Examples of the developing liquid include sodium carbonate (1% Na₂CO₃) and potassium carbonate (K₂CO₃).

When the resulting structure is etched, a resist-coated portion is not etched. On the other hand, the electrolytic-copper plated layer 25, the electroless-copper plated layer 24, and the copper layer 21 of the CCL which are not coated with the resist pattern are removed by an etching process.

The etching resist is removed by use of a stripping liquid. KOH or NaOH is generally used as the stripping liquid.

FIG. 2D shows the PCB on which the etching resist has been removed by the stripping liquid.

Alternative process of forming the circuit pattern will be described, below.

FIGS. 3A to 3D schematically illustrate the fabricating process of the PCB, which is called “semi-additive process” frequently used recently. FIGS. 3A to 3D may be substituted by FIGS. 1C to 1E in the “semi-additive process”. The term “semi-additive process” generally means 10 a process of forming the circuit pattern using a conventional selective plating method, but in the present specification, “semi-additive process” means a process conducted according to the following description.

The semi-additive process is useful to precisely form a thin pattern, and is characterized in that a polyimide film is used instead of the CCL and drilled by a laser drilling process in place of a mechanical drilling process.

FIG. 3A shows the CCL through which a hole is formed by the laser drilling process, and which is electroless-copper plated to form a film with a thickness of 0.5 to 1.5 μm thereon. Even though the hole seems to form a rectangle in FIG. 3A, in practice the hole actually forms a trapezoid, with its upper sectional area being larger than its lower sectional area if a laser beam is downwardly fired from an upper side of the CCL. On the other hand, if the laser beam is upwardly fired from an underside of the CCL, the hole forms the trapezoid with its lower sectional area being larger than its upper sectional area.

Alternatively, the CCL through which the hole is formed may be subjected to a sputtering process instead of the electroless-copper plating process. That is to say, a Cr layer with a thickness of 0.2 μm and a Cu layer with a thickness of 0.5 μm may be formed on the CCL by the Cr sputtering process.

In FIG. 3B, as described above, a plating resist 35 is formed on the Cu—Cr-plated CCL using the artwork film on which the dry film (D/F) and the circuit pattern are printed. At this time, a portion on which the plating resist is formed is not plated.

Additionally, in FIG. 3C, an electrolytic-copper plated layer 36 is formed in a thickness of 15 to 25 μm on the CCL on which the electroless-copper plated layer is formed. At this time, a portion coated with the plating resist is not plated, but a remaining portion is plated with a conductive copper.

The copper-plated CCL is then etched to remove the portion which is not copper-plated. That is to say, the electroless-copper plated layer (or Cr/Cu plated portion) and the copper layer of the CCL on which the plating resist 36 is coated are removed to expose the insulating layer of the CCL.

Furthermore, FIG. 3D is a sectional view of the PCB on which a desired wire pattern is formed.

Turning to FIG. 1F, the insulating ink is filled in the via hole of the CCL, the photo solder resist (PSR) 17 is coated on the CCL, and the solder resist of the connection part 18 to which other substrates or chips are connected is removed to expose the copper foil of the connection part.

In the PCB employing a BGA inter-connection technology, a lead line for connecting the PCB to other substrates or chips does not exist and a solder bump is formed on the CCL instead of the connection part 18 unlike a conventional lead frame technology, so other substrates or chips are electrically connected to the PCB through the solder bump.

Furthermore, the CCL is surface-treated so as to prevent oxidization of the copper foil without being coated by the solder resist, improve solderability of electronic parts mounted on the PCB,-and provide excellent conductivity to the copper foil.

Examples of a surface treatment of a copper plated substrate include a hot solder air leveling (HSAL) process, an organic solderability percervatives (OSP: a pre-flux coating process) process, an electroless-Ni/Au plating process, an electroless-Pd plating process, an electroless-Ag plating process., and an electroless-tin plating process.

Of these, the electroless-Ni/Au plating process is mostly applied to portable phones and a video cameras, in which the copper-plated substrate is plated with nickel and then plated with gold so as to increase adhesiveness of the gold to the copper-plated substrate.

In FIG. 1G, a portion from which the solder resist is removed is plated according to the electroless-Ni/Au plating process 19. This ending process of the PCB fabricating prevents the oxidization of the copper foil which is not coated with the solder resist, improving the solderability of electronic parts mounted on the PCB, and providing excellent conductivity to the copper foil.

Besides the fabricating processes of the PCB as described above, there are various other fabricating processes of the PCB.

In the case of the PCB whose both sides are electrically connected to each other through conventional via holes, the inner wall of each via hole functions to electrically connect both sides of the PCB to each other, so the inner wall should be carefully protected because a short circuit may occur when the inner wall is poorly plated. Therefore, a thickness of the copper layer plated on the inner wall of the via hole and the amount of ink filled in the via hole are critical factors in fabricating the PCB with the via hole.

However, it is difficult to desirably protect the plated layer on the inner wall of the via hole because the via hole playing an important role in the PCB has a very small size, and to fabricate the PCB with the via holes in accordance with the recent trend of lightness, compactness and smallness of PCB packages.

### SUMMARY OF THE INVENTION

[symbol]

[symbol]

[symbol]

[symbol]

[symbol]

[symbol]

Therefore, it is an object of the present invention to provide a method of fabricating a double-sided PCB without via holes, in which a predetermined circuit pattern including wires, acting as the via holes functioning to transmit electrical signals between both sides of the PCB, is formed on a flexible substrate, and the patterned flexible PCB is then folded to form the double-sided PCB without via holes.

It is another object of the present invention to provide a method of fabricating a double-sided PCB without via holes, which omits efforts for forming and protecting the via holes to easily meet the recent trend of lightness, compactness and smallness of PCB packages, and reduces its fabricating cost and time due to simplicity of the method.

The present invention provides a double-sided printed circuit board, comprising twofold insulating layers formed by folding one flexible insulating substrate, circuit patterns formed on an upper layer and a lower layer of the folded insulating substrate while passing over a folded portion of the insulating substrate, a solder resist layer for protecting the circuit patterns, and a plurality of connection parts to be connected to other substrates or chips, which is electrically connected by the said circuit patterns.

Further, the present invention provides a method of fabricating a double-sided printed circuit board, comprising forming a circuit pattern on a copper-plated side of a flexible insulating substrate, said flexible insulating substrate being plated with copper on only one side thereof, coating a photo solder resist on a patterned side of the flexible insulating substrate and removing a portion of the photo solder resist acting as a connection to be connected to other substrates and chips, surface-treating the portion from which the photo solder resist has been removed, and folding the resulting structure according to a predetermined folding process to form a double-sided printed circuit board. Furthermore, the present invention provides a method of fabricating a double-sided printed circuit board, comprising determining portions to be an individual printed circuit board unit and to be folded, on a rigid insulating substrate having a size capable of including a plurality of printed circuit boards, cutting the folded portions other than areas at which the folded portions meet each other, attaching a flexible insulating substrate to the rigid insulating substrate, said flexible insulating substrate having one side plated with copper, forming a circuit pattern on the copper-plated side of the flexible insulating substrate, coating a photo solder resist on the patterned side of the flexible insulating substrate and removing a portion of the photo solder resist acting as a connection part to be connected to other substrates and chips, surface-treating the portion from which the photo solder resist has been removed, and folding the resulting structure according to a predetermined folding process to form a double-sided printed circuit.

Moreover, the present invention provides a method of fabricating a double-sided printed circuit board, comprising forming a circuit pattern on a copper-plated side of a flexible insulating substrate, said flexible insulating substrate being plated with copper on only one side thereof; coating a photo solder resist on a patterned side of the flexible insulating substrate and removing a portion of the photo solder resist acting as a connection part to be connected to other substrates and chips; surface-treating the portion from which the photo solder resist has been removed so as to be connected to other substrates and chips; attaching a rigid substrate to a non-patterned side of the flexible insulating substrate, said rigid substrate being cut along a line along which the rigid substrate is folded; and folding the resulting structure according to a predetermined folding process to form a double-sided printed circuit board.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A to 1G are sectional views, stepwisely illustrating a fabricating-process of a conventional double-sided PCB;

FIGS. 2A to 2D are sectional views, stepwisely illustrating a conventional process of forming a circuit pattern on the PCB, which can replace FIGS. 1C to 1E;

FIGS. 3A to 3D are sectional views, stepwisely illustrating another conventional process of forming the circuit pattern on the PCB, which can replace FIGS. 1C to 1E;

FIGS. 4A to 4D stepwisely illustrate a fabricating process of a double-sided PCB without via holes according to the first embodiment of the present invention, in which a circuit pattern is formed on one side of the PCB;

FIGS. 5A to 5C stepwisely illustrate a process of folding a flexible substrate according to the present invention;

FIGS. 6A to 6H stepwisely illustrate a fabricating process of a double-sided PCB without via holes according to the second embodiment of the present invention, in which after a rigid substrate is processed, a flexible substrate is attached to the rigid substrate, and a circuit pattern is then formed on one side of the double-sided PCB;

FIGS. 7A to 7E stepwisely illustrate a fabricating process of a double-sided PCB without via holes according to the third embodiment of the present invention, in which after a circuit pattern is formed on a flexible substrate, a rigid substrate is attached to the flexible substrate; and

FIGS. 8A to 8E stepwisely illustrate a fabricating process of a double-sided PCB without via holes according to the fourth embodiment of the present invention, in which after a circuit pattern is formed on a flexible substrate, a rigid-substrate is attached to the flexible substrate while a portion of the rigid substrate is removed.

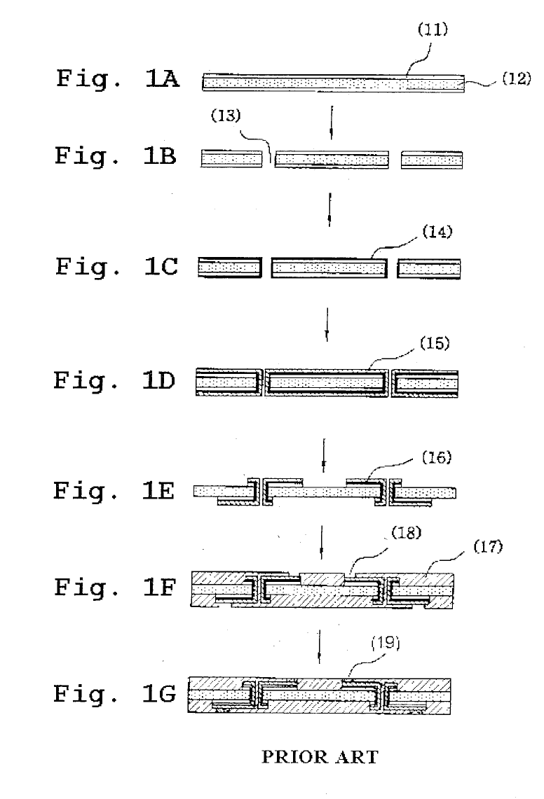

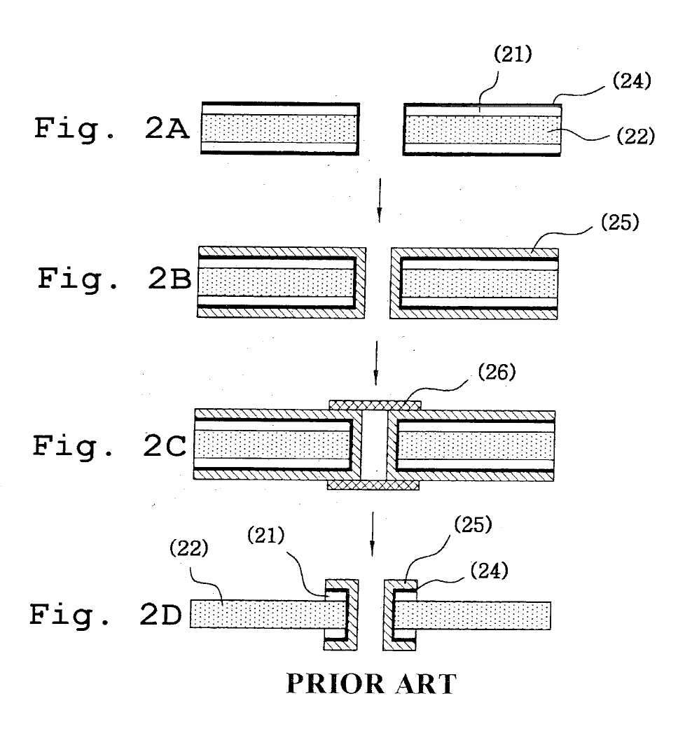

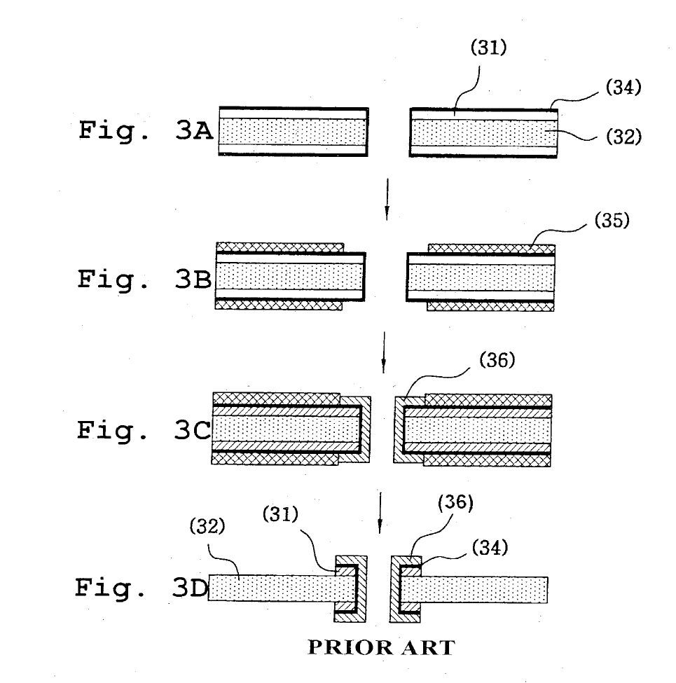

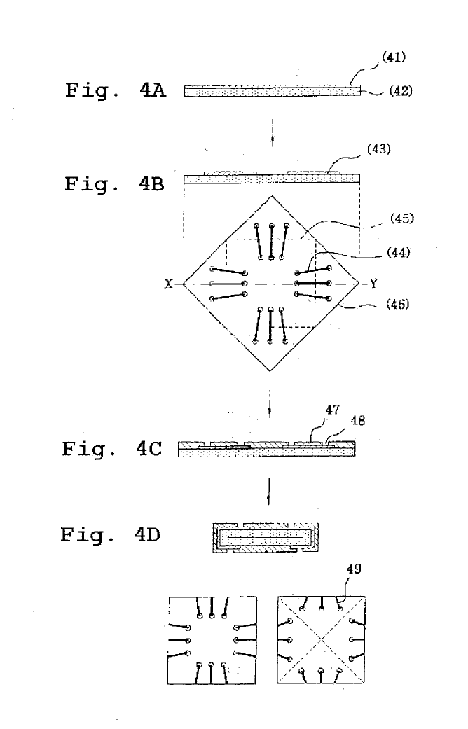

### DETAILED DESCRIPTION OF THE INVENTION

Reference now should be made to the drawings, in which the same reference numerals are used throughout the different drawings to designate the same or similar components.

A detailed description will now be given of a method of fabricating a double-sided PCB without via holes according to a first embodiment of the present invention, below.

FIGS. 4A to 4D stepwisely illustrate the fabricating process of the PCB according to the first embodiment of the present invention.

In detail, FIG. 4A is a sectional view of a substrate in which a thin copper film 41 is plated on a flexible insulating layer 42. At this time, the copper film 41 is plated on only one side of the insulating layer 42.

Furthermore, the substrate on which the copper film is already plated may be used, or the copper film may be plated on the flexible insulating layer during fabricating the PCB.

The flexible insulating layer 42 may be made of a polyimide film.

Additionally, FIG. 4B is a sectional and a top view of the flexible substrate on which a copper circuit pattern is formed. The sectional view of the substrate is taken along the line X-Y of the top view.

As described above, there are various processes of forming the circuit pattern, and the processes depend on physical properties of the substrate and fabricating conditions of the PCB.

In FIG. 4B, the reference numeral 43 does not denote the copper film 41 of FIG. 4A, but rather denotes the circuit pattern formed by a layering and an etching process.

Additionally, the reference numeral 44 of FIG. 4B denotes lead lines for replacing the via holes electrically connecting both sides of a conventional double-sided PCB to each other. These lead lines are not separated from the substrate, but formed simultaneously with the other circuit patterns by an etching or a plating process as designed in circuit designing process. In other words, FIG. 4B is drawn in order to illustrate; but in practice the lead lines 44 are indistinguishable from the circuit pattern unless they are separately marked. The circuit pattern is not shown in FIG. 4B. Further, the substrate is to be folded along a dotted line 45.

With reference to FIG. 4C, a photo solder resist (PSR) is coated on the patterned substrate, and a portion of the photo solder resist located on a connection part 48 is then removed using a printed mask film. At this time, the connection part 48 is to be connected to other-type substrates or chips at last.

The photo solder resist which is not to be removed is designated by the reference numeral 47, and the connection part 48 is to be connected to other types of substrates or chips, as described above.

FIG. 4D shows a sectional view, a top view, and a bottom view of the flexible substrate as it is being folded along the dotted line 45 of FIG. 4B.

In FIG. 4D, the circuit pattern and the PSR are not shown in the top and bottom view.

Likewise, the lead lines 49 shown in the top and bottom view function to substitute the via holes of the conventional PCB, and FIG. 4D is drawn in order to illustrate; but in practice the lead lines 49 are indistinguishable from the circuit pattern unless they are separately marked.

According to the present invention, the resulting double-sided PCB fabricated using the flexible insulating layer is applied to fields in which a rigid PCB is used even though the flexible insulating layer is used as a base substrate.

Furthermore, a method of folding four apexes of the flexible substrate as shown in FIGS. 4A to 4D may be implemented differently.

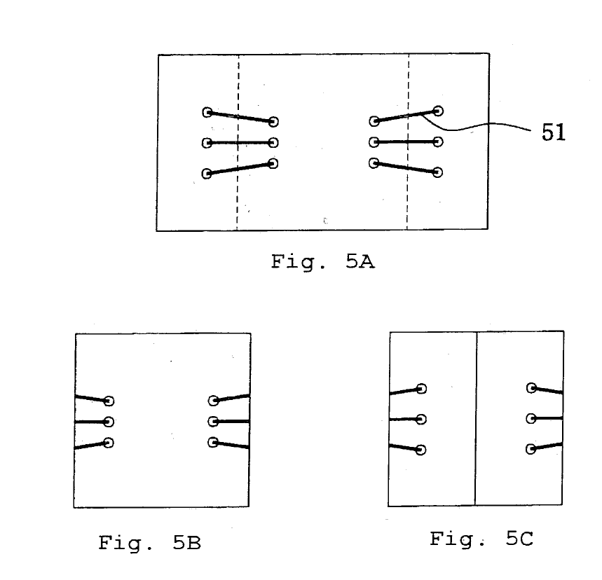

For example, as in FIGS. 5A to 5C, both sides of the flexible substrate may be folded in such a way that a folded portion forms a rectangle. In detail, FIG. 5A is a top view of the flexible substrate before it is folded, FIG. 5B is a top view of the folded flexible substrate, and FIG. 5C is a bottom view of the folded flexible substrate.

As described above, the lead lines 51 shown in the top and bottom view function to substitute the via holes of the conventional PCB, and FIGS. 5A to 5D are drawn in order to illustrate; but in practice the lead lines 51 are indistinguishable from the circuit pattern unless they are separately marked.

FIGS. 4A to 4D and FIGS. 5A to 5C illustrate the case of fabricating only one flexible substrate, but when the double-sided PCB is commercially fabricated, up to hundreds flexible substrates may be produced from one panel according to fabrication conditions and use of the PCB, so it can be understood that modifications of the present invention, for example, various shapes of substrates and various folding methods of the substrate, will be apparent to those skilled in the art unless the modifications depart from the spirit of the invention.

Additionally, a rigid material may be inserted between the flexible substrates so as to improve strength of the flexible substrate.

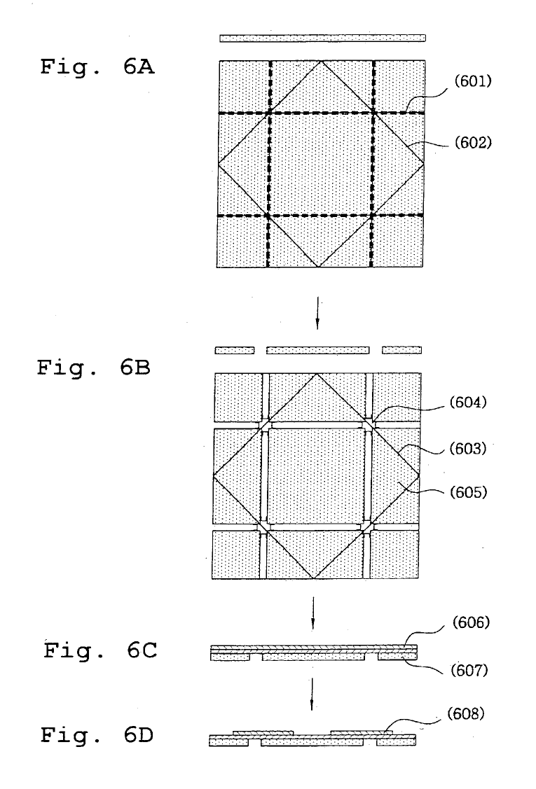

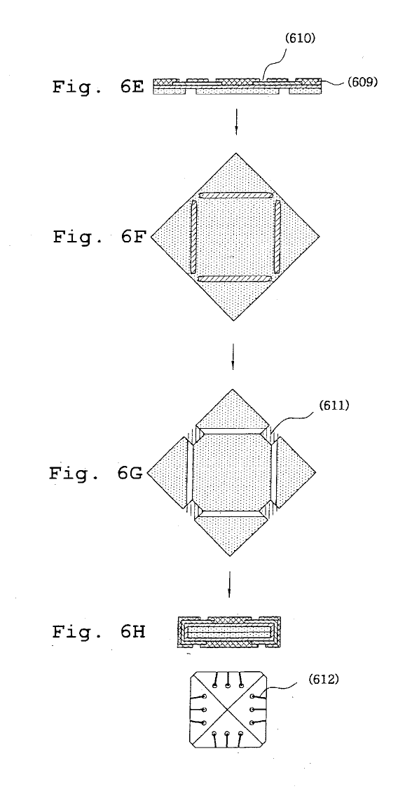

According to a second embodiment of the present invention, there is illustrated a process of stepwisely fabricating a PCB in which a rigid material is inserted into the PCB to improve strength of the PCB, as shown in FIGS. 6A to 6H.

Prepreg, inserted between layers of a multi-layered board or any material having strength sufficient to support each flexible layer, may be used as the rigid material, but it is preferable to use an insulating material as the rigid material in consideration of electric properties of the substrate.

FIG. 6A partially illustrates a sectional view (an upper view) and a top view (a lower view) of the rigid substrate, but the rigid substrate before being cut is as large as a mother board on which the PCB is to be mounted. In other words, the cut rigid substrate is used to fabricate the double-sided PCB.

In FIG. 6A, the rhombic solid line 602 denotes an area corresponding to a unit of the PCB and the dotted line 601 denotes a portion which is to be folded. As described below, the dotted line 601 will be subjected to a cutting process.

FIG. 6B is a sectional view and a top view of the substrate in which the dotted line 601 of FIG. 6A has been cut. At this time, the dotted line is not wholly cut, but only partially cut. That is to say, a portion 604 at which the dotted line meets the rhombic solid line 602 is not cut, thereby preserving a whole shape of the substrate.

Referring to FIG. 6C, there is illustrated a sectional view of the flexible substrate which is coated with a conductive layer 606 on one side thereof and the rigid substrate 607 on the other side thereof.

FIG. 6D is a sectional view of a flexible-rigid substrate in which the rigid substrate is attached to the patterned flexible substrate. As in FIG. 6D, a procedure of forming the circuit pattern is not shown in order to simply illustrate the flexible-rigid substrate, and the circuit pattern may be formed by various methods as described above. The reference numeral 608 in FIG. 6D does not denote a portion of the conductive layer 606 remaining after being subjected to some processes such as an etching process on the flexible substrate, but rather represents the circuit pattern acting as a conductive path functioning to connect signals between an upper side and a lower side of the double-sided PCB.

With reference to FIG. 6E, illustrated hereby is the flexible-rigid substrate in which the photo solder resist 609 is coated on the substrate of FIG. 6D and a connection part 610 connected to other-type substrates or chips is etched.

When the connection part 610 is etched, there is needed an artwork film onto which the circuit pattern is printed, as well as a separate mask film.

FIG. 6F is a bottom view of an individual PCB unit, which is cut along the solid line 602 of FIG. 6A. In other words, the individual PCB unit is processed after the substrate, including a plurality of units, is divided into individual units. The flexible substrate on which the photo-resist is coated is attached to an upper side of the individual unit.

As in FIG. 6G, overlapped portions 611, between adjacent corners of the substrate when four corners are folded, are removed.

Furthermore, as shown in FIG. 6H, the substrate is folded along the dotted line 601 of FIG. 6A in such a way that the rigid layer is positioned inside the folded flexible-rigid substrate, thereby accomplishing the desired double-sided PCB. In the top view of FIG. 6H, only the lead lines 612 are shown; the circuit pattern and photo solder resist layer are not shown. However, in practice, the lead lines 612 are indistinguishable from the circuit pattern unless they are separately marked.

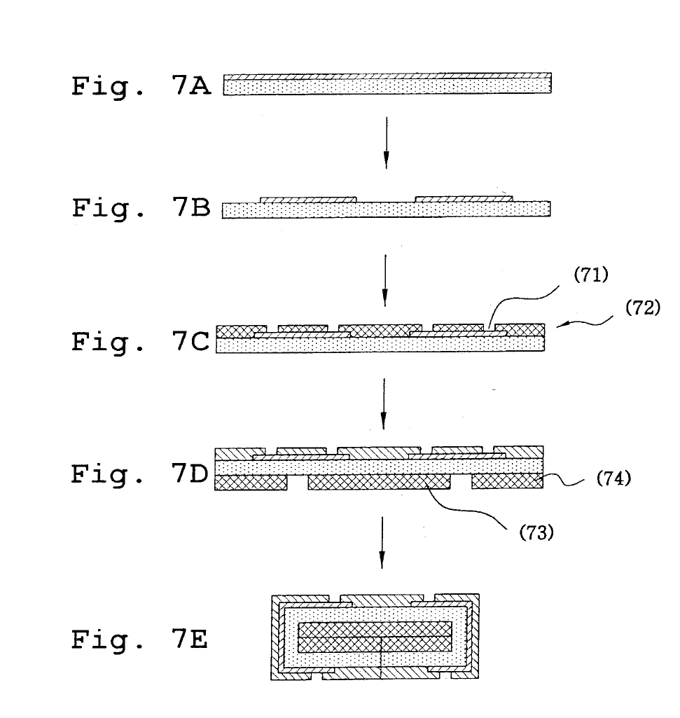

According to a third embodiment of the present invention, there is illustrated a method of fabricating a double-sided PCB in which a rigid layer is inserted into the PCB as shown in FIGS. 7A to 7E.

The process shown in FIGS. 7A to 7C remains the same as that of FIGS. 4A to 4D, without using the rigid layer.

FIG. 7C illustrates the flexible PCB 72 on which the connection part 71, connected to other-type substrates or chips, is removed and the photo solder resist layer is formed.

In FIG. 7D, the rigid substrate 73 is attached to the flexible PCB 72 while a portion of the rigid substrate 73 which is to be folded, has been previously cut.

Referring to FIG. 7E, the resultant structure is folded in such a way that the rigid substrate 73 is positioned inside the folded structure, thereby accomplishing the rigid double-sided PCB without via holes.

Meanwhile, there are various methods of inserting the rigid substrate into the PCB.

For example, when the PCB is fabricated according to processes of FIGS. 6A to 6H and FIGS. 7A to 7E, the rigid substrate is folded to form a twofold layer, thus thickening the whole PCB, as shown in FIGS. 6H and 7E.

To avoid this overly thick PCB, the folded corner part 605 of the rigid substrate of FIG. 6B may be removed during a cutting process of the rigid substrate, or a portion 74 of FIG. 7D may be removed, thereby causing the rigid substrate inserted into the PCB to be one layer. At this time, when the PCB strip is divided into individual units, the flexible substrate is broader than the rigid substrate, unlike FIGS. 6A to 6H.

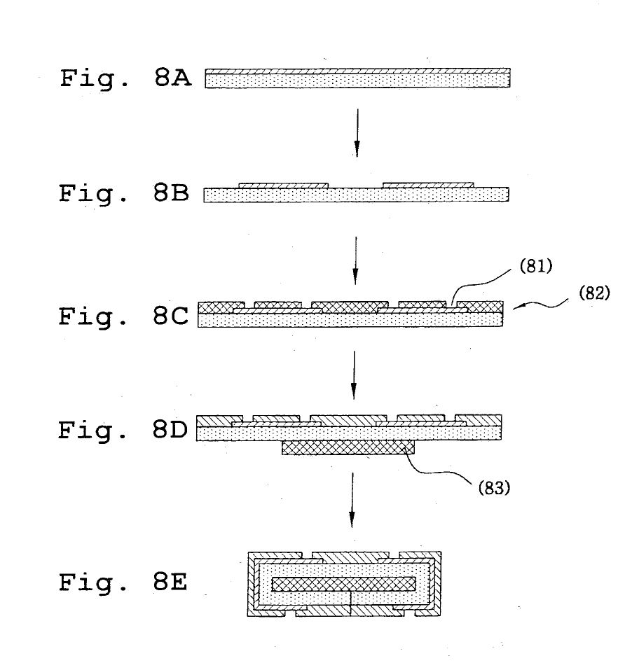

According to a fourth embodiment of the present invention, as shown in FIGS. 8A to 8E, illustrated is a method of fabricating a double-sided PCB in which the portion 74 of FIG. 7D is removed.

The process shown in FIGS. 8A to 8C remains the same as both the process of FIGS. 4A to 4C, without using the rigid supporting layer and the process of FIGS. 7A to 7E in which the rigid substrate is attached to the flexible substrate after the circuit pattern is formed on the flexible substrate.

FIG. 8C illustrates the flexible PCB 82 in which the connection part 81, connected to other types of substrates or chips, is removed and the photo solder resist layer is formed.

With reference to FIG. 8D, the rigid substrate 83 is attached to the flexible PCB while removing unnecessary portions, which cause the resulting double-sided PCB to be thickened, from the rigid substrate 83.

The resulting double-sided PCB is then folded in a predetermined manner, thereby accomplishing the desired double-sided PCB without via holes in FIG. 8E. At this time, the desired double-sided PCB includes a single-layered rigid substrate.

As described above, the present invention provides a double-sided PCB without via holes fabricated by folding a patterned flexible substrate. At this time, a predetermined circuit pattern including lead lines acting as the via holes, functioning to transport electrical signals between both sides of the PCB, is formed on the flexible substrate.

Furthermore, a method of fabricating the double-sided PCB without via holes according to the present invention saves the efforts for forming and protecting the via holes to satisfy the recent trend of lightness, compactness and smallness of PCB packages, and reduces the cost and time of PCB packages fabricating due to the simplicity of this method.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

What is claimed is:

1. A double-sided printed circuit board, comprising:
twofold insulating layers formed by folding one flexible insulating substrate;
circuit patterns formed on an upper layer and a lower layer of the folded insulating substrate while passing over a folded portion of the insulating substrate between the upper layer and the lower layer; [symbol]
a solder resist layer for protecting the circuit patterns; and
a plurality of connection parts to be connected to other substrates or chips, which is electrically connected by the said circuit patterns.

2. The double-sided printed circuit board as set forth in claim 1, wherein the flexible insulating substrate is a rectangular substrate which is folded in such a way that its four corners come together at a center of the rectangular flexible insulating substrate.

3. The double-sided printed circuit board as set forth in claim 1, wherein the flexible insulating substrate is a rectangular substrate which is folded in such a way that its two opposite sides come together at a central line of the flexible insulating substrate.

4. The double-sided printed circuit board as set forth in claim 1, wherein the flexible insulating substrate is folded in such a way that the insulating substrate surrounds at least one rigid substrate.

5. The double-sided printed circuit board as set forth in claim 4, wherein the flexible insulating substrate is folded in such a way that the insulating substrate surrounds at least two rigid substrates.

6. The double-sided printed circuit board as set forth in claim 4 or 5, wherein the rigid substrate is made of prepreg.

7. A method of fabricating a double-sided printed circuit board, comprising:
forming a circuit pattern on a copper-plated side of a flexible insulating substrate, said flexible insulating substrate being plated with copper on only one side thereof; coating a photo solder resist on a patterned side of the flexible insulating substrate and removing a portion of said photo solder resist acting as a connection part to be connected to other substrates and chips;
surface-treating the portion from which the photo solder resist has been removed; and
folding the resulting structure according to a predetermined folding process to form a double-sided printed circuit board.

8. The method as set forth in claim 7, wherein the flexible insulating substrate is made of a polyimide film.

9. The method as set forth in claim 7, wherein the forming of the circuit pattern comprises:
electroless-copper plating the flexible insulating substrate;
electrolytic-copper plating the electroless-copper plated insulating substrate;
constructing an etching resist pattern on the electrolytic-copper plated substrate using a dry film;
etching the resulting substrate; and
removing the etching resist pattern from the etched substrate with a stripping liquid.

10. The method as set forth in claim 9, wherein an electroless-copper plated layer formed on the flexible insulating substrate is 0.5 to 1.5 μm in thickness, and an electrolytic-copper plated layer formed on the electroless-copper plated layer is 15 to 25 μm in thickness.

11. The method as set forth in claim 7, wherein the forming of the circuit pattern comprises:
electroless-copper plating the flexible insulating substrate to form a first copper layer with a thickness of 0.5 to 1.5 μm on the flexible insulating substrate;
constructing a plating resist pattern on the electroless-copper plated substrate using a dry film;
electrolytic-copper plating the resulting substrate to form a second copper layer with a thickness of 15 to 25 μm on the resulting substrate; and
etching the resulting substrate to remove all portions other than the insulating layer at areas not electrolytic-copper plated.

12. The method as set forth in claim 7, wherein the forming of the circuit pattern comprises:
sputtering the flexible insulating substrate to form a Cr layer with a thickness of 0.2 μm and a Cu layer with a thickness of 0.5 μm on the flexible insulating substrate;
constructing a plating resist pattern on the sputtered substrate using a dry film;
electrolytic-copper plating the resulting substrate to form a copper layer with a thickness of 15 to 25 μm on the resulting substrate; and
etching the resulting substrate to remove all portions other than the insulating layer at areas not electrolytic-copper plated.

13. The method as set forth in claim 7, wherein the predetermined folding process comprises:
designing the flexible insulating substrate in a square shape, and
folding the flexible insulating substrate in such a way that four corners of the square flexible insulating substrate come together at a center of the insulating substrate.

14. The method as set forth in claim 7, wherein the predetermined folding process comprises:
designing the flexible insulating substrate in a rectangular shape, and
folding the flexible insulating substrate in such a way that its two opposite sides come together at a central line of the flexible insulating substrate.

15. A method of fabricating a double-sided printed circuit board, comprising:
determining portions to be an individual printed circuit board unit and to be folded, on a rigid insulating substrate having a size capable of including a plurality of printed circuit boards; cutting the folded portions other than areas at which the folded portions meet each other;
attaching a flexible insulating substrate to the rigid insulating substrate, said flexible insulating substrate having one side plated with copper;
forming a circuit pattern on the copper-plated side of the flexible insulating substrate;
coating a photo solder resist on the patterned side of the flexible insulating substrate and removing a portion of the photo solder resist acting as a connection part to be connected to other substrates and chips;
surface-treating the portion from which the photo solder resist has been removed; and
folding the resulting structure according to a predetermined folding process to form a double-sided printed circuit board.

16. The method as set forth in claim 15, further comprising removing parts of the rigid substrate layer which make twofold rigid substrate layers after folding step, so as to form only one rigid substrate layer in the folded double-sided printed circuit board, between the cutting step and the attaching step.

17. The method as set forth in claim 15 or 16, wherein the flexible insulating substrate is made of a polyimide film.

18. The method as set forth in claim 15 or 16, wherein the rigid insulating substrate is made of prepreg.

19. The method as set forth in claim 15 or 16, wherein the forming of the circuit pattern comprises:
electroless-copper plating the flexible insulating substrate to form a first copper layer with a thickness of 0.5 to 1.5 μm on the flexible insulating substrate;
constructing a plating resist pattern on the electroless-copper plated substrate using a dry film;
electrolytic-copper plating the resulting substrate to form a second copper layer with a thickness of 15 to 25 μm on the resulting substrate; and
etching the resulting substrate to remove all portions other than the insulating layer at areas not electrolytic-copper plated.

20. The method as set forth in claim 15 or 16, wherein the forming of the circuit pattern comprises:
sputtering the flexible insulating substrate to form a Cr layer and a Cu layer on the flexible insulating substrate;
constructing a plating resist pattern on the sputtered substrate using a dry film;
electrolytic-copper plating the resulting substrate to form a copper layer with a thickness of 15 to 25 μm on the resulting substrate; and
etching the resulting substrate to remove all portions other than the insulating layer at areas not electrolytic-copper plated.

21. A method of fabricating a double-sided printed circuit board, comprising:
forming a circuit pattern on a copper-plated side of a flexible insulating substrate, said flexible insulating substrate being plated with copper on only one side thereof;
coating a photo solder resist on a patterned side of the flexible insulating substrate and removing a portion of the photo solder resist acting as a connection part to be connected to other substrates and chips;
surface-treating the portion from which the photo solder resist has been removed so as to to be connected to other substrates and chips;
attaching a rigid substrate to a non-patterned side of the flexible insulating substrate, said rigid substrate being cut along a line along which the rigid substrate is folded; and
folding the resulting structure according to a predetermined folding process to form a double-sided printed circuit board.

22. The method as set forth in claim 21, wherein the rigid substrate is designed in such a way that twofold rigid substrate layers are surrounded by the flexible insulating substrate after the folding step.

23. The method as set forth in claim 21, wherein the rigid substrate is designed in such a way that one rigid substrate layer is surrounded by the flexible insulating substrate after the folding step.
